(19) United States
(12) Patent Application Publication
(10) Pub. No.: US 2024/0387272 A1
(43) Pub. Date: Nov. 21, 2024

(54) FINFET DEVICE STRUCTURE AND METHOD

(71) Applicant: Taiwan Semiconductor Manufacturing Company, Ltd., Hsinchu (TW)

(72) Inventors: Zhen-Nong Wu, Taoyuan (TW); Mao-Chia Wang, Tainan (TW); Jia-Ren Chen, Tainan (TW); Li-Yi Chen, Tainan (TW); Wen Han Hung, Tainan (TW); Che-Li Lin, Kaohsiung (TW); Yen-Ning Chen

(21) Appl. No.: 18/197,968

(22) Filed: May 16, 2023

(51) Int. Cl. H01L 21/8234; H01L 27/088

(52) U.S. Cl. CPC H01L 21/823431; H01L 21/823481; H01L 27/0886

(57) ABSTRACT

A method for forming a semiconductor device. The method includes performing a first etching process to define one or more fins and corresponding device isolation structures on a substrate. The method further includes forming an enhancement layer on each of the fins, such that the enhancement layer encapsulates each fin. The method further performs a second etching process to remove one or more of the fins, and performs a third etching process to remove a portion of the enhancement layer. The method also includes depositing an STI material on the fins and the device isolation structures, followed by recessing the fins relative to the STI material.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a semiconductor device. For example, a three dimensional transistor, such as a fin-like field-effect transistor (Fin-FET), has been introduced to replace a planar transistor. In the manufacturing process of the Fin-FET devices, further improvements are constantly necessary to satisfy the performance requirement in the scaling down process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1J illustrate various cross-sectional views of intermediate stages in the fabrication of fins of a FinFET structure in accordance with some embodiments.

FIGS. 2A-2M illustrate various three-dimensional views of intermediate stages in the fabrication of fins of a FinFET structure in accordance with some embodiments.

FIG. 3 illustrates a three-dimensional representative example of a FinFET device in accordance with some embodiments.

FIG. 4 illustrates a comparative illustration of the use of an enhancement layer during fin formation in accordance with some embodiments.

FIG. 5 illustrates a comparative illustration of the use of an enhancement layer during fin formation in accordance with some embodiments.

FIGS. 6A-6B illustrate various cross-sectional views of intermediate stages in the fabrication of fins of a FinFET structure in accordance with some embodiments.

FIG. 7 illustrates a method of fabricating a FinFET structure in accordance with some embodiments.

FIG. 8 illustrates a method of fabricating a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

As the semiconductor industry has strived for higher device density, higher performance, and lower costs, problems involving both fabrication and design have been encountered. One solution to these problems has been the development of a fin-like field effect transistor (FinFET). A FinFET includes a thin vertical ‘fin’ formed in a free-standing manner over a major surface of a substrate. The source, drain, and channel regions are defined within this fin. The transistor's gate wraps around the channel region of the fin. This configuration allows the gate to induce current flow in the channel from three sides. Thus, FinFET devices have the benefit of higher current flow and reduced short-channel effects.

The dimensions of FinFETs and other metal oxide semiconductor field effect transistors (MOSFETs) have been progressively reduced as technological advances have been made in integrated circuit materials. For example, high-k metal gate (HKMG) processes have been applied to FinFETs. However, in low density areas, e.g., ISO areas, plasma etching shrinks, i.e., reduces the profile of the edge fins of a FinFET. This reduced fin profile may reduce quality of FinFETs, and lead to device breakdown. In some embodiments, formation of a surface nitridation layer prior to oxide deposition provides an etch stop layer protecting the end or edge fins of a FinFET from shrinkage occurring during etching processes.

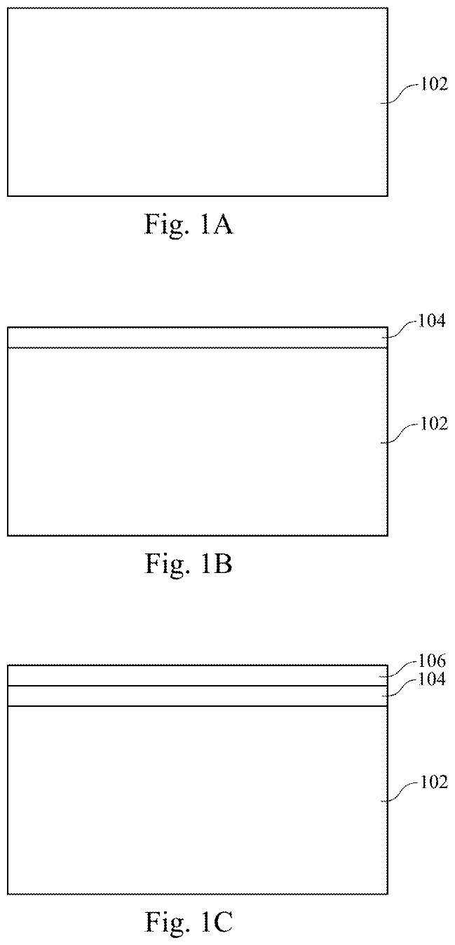

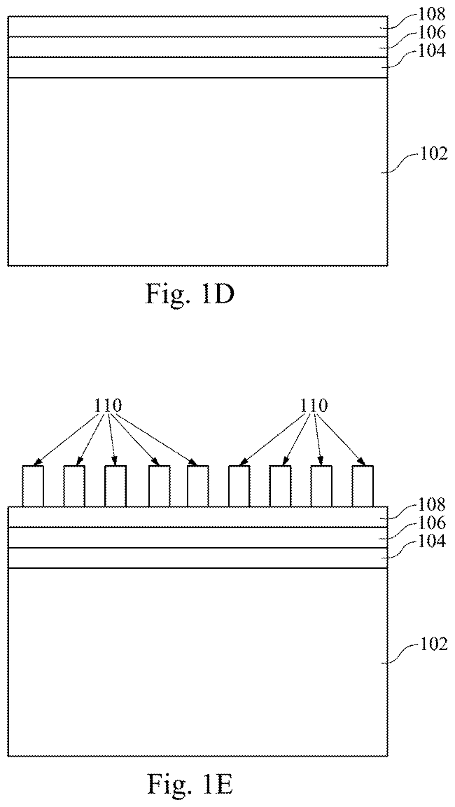

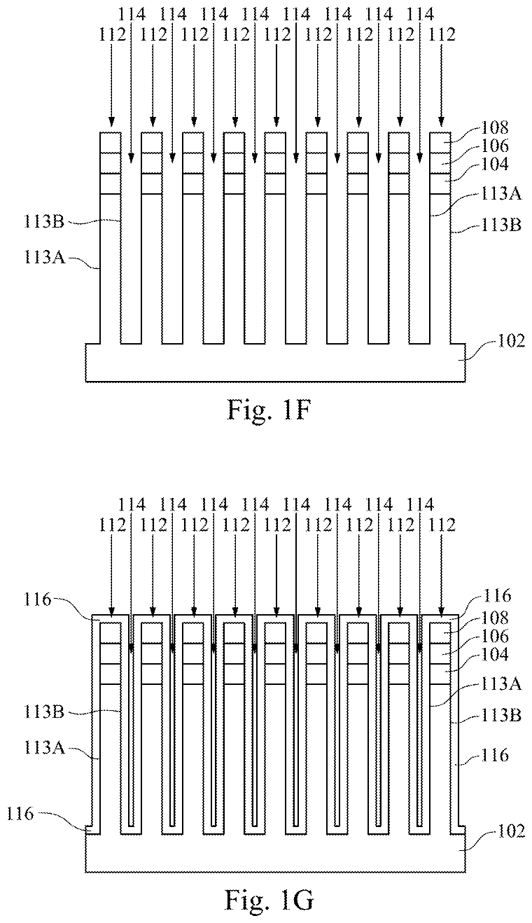

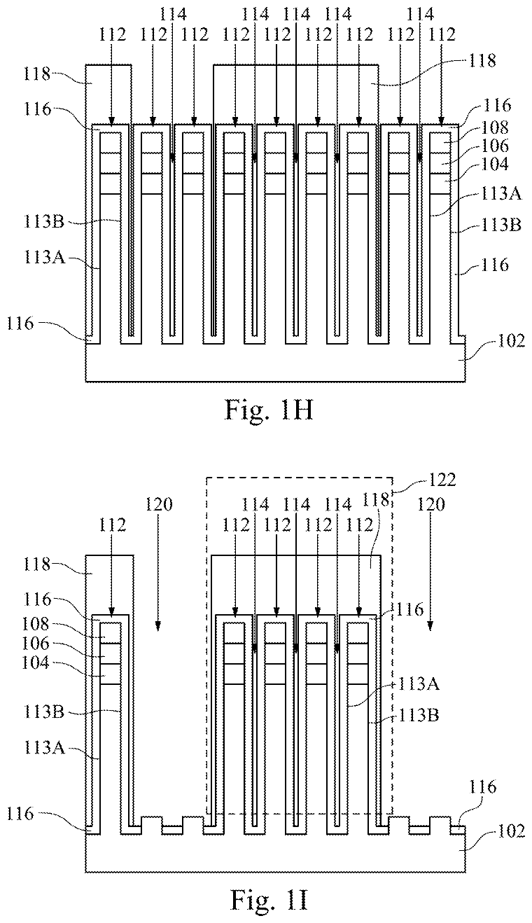

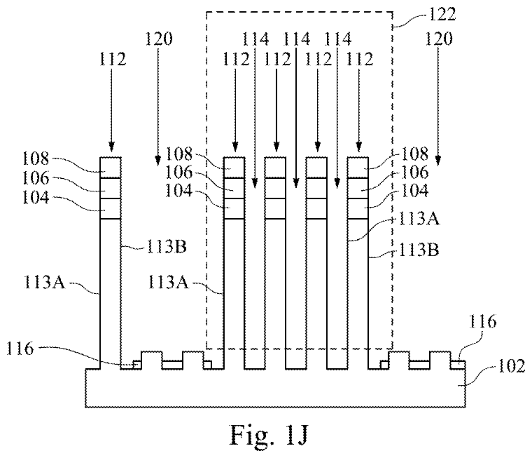

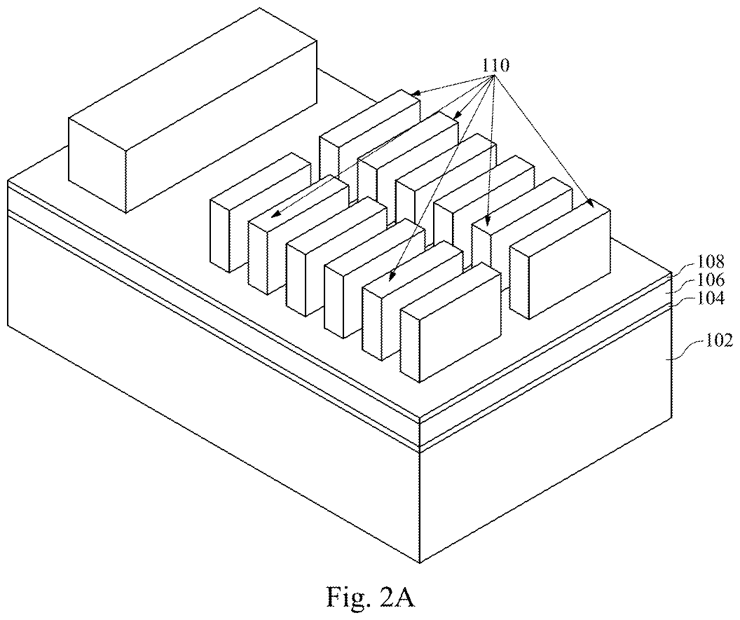

Turning now to FIGS. 1A-1J, there are shown various cross-sectional views of intermediate stages in the fabrication of a fin of a FinFET structure in accordance with some embodiments. In the following, various layers or films are deposited and patterned. The patterning of a layer may employ any suitable patterning technique such as a photolithographic patterning technique using deposition of a photoresist layer and selective exposure via a photomask to visible light, ultraviolet light, deep ultraviolet light (i.e., DUV lithography), extreme ultraviolet light (i.e. EUV lithography), or so forth, followed by development of the exposed photoresist and subsequent etching, deposition or other process steps laterally delineated by the developed photoresist. In other embodiments, patterning of an electron-sensitive resist layer may be by way of electron beam exposure (electron beam lithography, i.e., e-beam lithography). The skilled artisan will appreciate that the foregoing are merely illustrative examples.

In FIG. 1A, a substrate 102 is provided. The substrate 102 may be a semiconductor substrate, such as a bulk semiconductor substrate, a semiconductor-on-insulator (SOI) substrate, a multi-layered or gradient substrate, or the like. The substrate 102 may include a semiconductor material, such as an elemental semiconductor including Si and Ge; a compound or alloy semiconductor including SiC, SiGe, GaAs, GaP, GaAsP, AlInAs, AlGaAs, GaInAs, InAs, GaInP, InP, InSb, and/or GaInAsP; or a combination thereof. The substrate 102 may be doped or undoped.

In accordance with one embodiment, a pad layer 104 is deposited on the substrate, as shown in FIG. 1B. In some embodiments, the pad layer 104 may comprise, for example and without limitation may be implemented as a suitable dielectric, i.e., insulative, material including, for example and without limitation, silicon dioxide (SiO₂) material, silicon nitride (SiNₓ) material, or the like. Suitable mechanisms for depositing the pad layer 104 may include, for example and without limitation, chemical vapor deposition (CVD), physical vapor deposition (PVD), atomic layer deposition (ALD), electroless plating, electrochemical plating, sputtering, ion metal plasma, another deposition process, or any suitable combination thereof.

As illustrated in FIG. 1C, a first insulative layer 106 is formed on the pad layer 104. As will be appreciated, the first insulative layer 106 may be deposited on the pad layer 102 by, for example, chemical vapor deposition (CVD), physical vapor deposition (PVD), atomic layer deposition (ALD), electroless plating, electrochemical plating, sputtering, ion metal plasma, another deposition process, or any suitable combination thereof and without limitation. In accordance with some embodiments, the first insulative layer 106 may comprise any suitable dielectric material including, for example and without limitation, silicon dioxide (SiO₂) material, silicon nitride (SiNₓ) material, or the like. In one example embodiment, the pad layer 104 and the first insulative layer 106 comprise different materials. In a further embodiment, the first insulative layer 106 may be deposited as a silicon nitride layer.

A hard mask layer 108 is then formed on the first insulative layer 106, as shown in FIG. 1D. In accordance with some embodiments, the hard mask layer 108 may comprise, for example and without limitation a nitride or an oxide material. As will be appreciated, deposition, such as, for example and without limitation, chemical vapor deposition (CVD), physical vapor deposition (PVD), atomic layer deposition (ALD), electroless plating, electrochemical plating, sputtering, ion metal plasma, another deposition process, or any suitable combination thereof, may be used for applying the hard mask layer 108 onto the first insulative layer 106.

A first photoresist 110 is then applied and patterned on the hard mask layer 108, as depicted in FIG. 1E. As shown in FIG. 1E, the first photoresist 110 is patterned to enable formation of the fins of the FinFET structure, as will be discussed in FIG. 1F-1J. The first photoresist 110 may include deposition of a layer of photoresist material on the hard mask layer 108, followed by subsequent patterning, i.e., exposure of light through a mask to develop portions of the photoresist material. That is, FIG. 1E illustrates the deposition of a photoresist layer and selective exposure via a photomask to visible light, ultraviolet light, deep ultraviolet light (i.e., DUV lithography), extreme ultraviolet light (i.e., EUV lithography), or so forth, followed by development of the exposed photoresist. The unexposed photoresist is then removed, resulting in the patterned first photoresist 110 shown in FIG. 1E.

Thereafter, portions of the substrate 102, the pad layer 104, the first insulative layer 106 and the hard mask layer 108 are removed. Suitable removal processes include, for example and without limitation, an etching process implemented as a dry etching process, plasma etching process, a RIE process, a wet etching process, some other etching process, or a combination of the foregoing. That is, those portions of the substrate 102, the pad oxide layer 104, the first insulative layer 106 and the hard mask layer 108 uncovered by the photoresist 110 are removed. Thereafter, the photoresist 110 is removed, resulting in the intermediate stage of fabrication shown in FIG. 1F.

As shown in FIG. 1F, a plurality of fins 112 are formed of the substrate 102. It will be appreciated that the number of fins 112 shown in FIG. 1F is intended solely as an example, and any number of fins may be used by the FinFET as determined in accordance with required design characteristics. It will be appreciated that each fin 112 depicted in FIG. 1F is substantially rectangular in shape, extending perpendicularly upward from the substrate 102. Further, as shown in FIG. 1F, each fin 112 includes a first sidewall 113A and a second sidewall 113B, which are depicted as being perpendicular to the substrate 102. The skilled artisan will appreciate that other forms, shapes and cross-sections of the fins 112 are capable of being implemented in accordance with varying embodiments of the subject application. In some embodiments, the thickness of the fins 112 is substantially uniform. In other embodiments, the thickness of the fins 112 may vary depending upon their respective locations, functions, and design requirements.

FIG. 1F further illustrates a plurality of device isolation structures or regions 114 formed between each fin 112 defined by the aforementioned sidewalls 113A-113B. In accordance with some embodiments, the device isolation structures 114 may correspond to local oxidation of silicon (LOCOS) regions, shallow trench isolation (STI), deep trench isolation (DTI), buffer oxide (BOX) regions, deep-well-formation, and the like.

Turning now to FIG. 1G, there is shown a further stage of fabrication of the FinFET device in accordance with one embodiment of the subject application. As depicted in FIG. 1G, an enhancement layer 116 is formed on the fins 112. In accordance with some embodiments, the enhancement layer 116 may comprise silicon, oxygen, nitrogen, or the like. In further embodiments, the enhancement layer 116 may include Si, O, C, N, P, As, B, and/or Ga of at least 1% atomic concentration. The aforementioned enhancement layer 116 may be deposited in a thickness in the range of about 1 A to 30 A. As will be appreciated, the enhancement layer 116 may be deposited on the fins 112, sidewalls 113A-113B, and device isolation structures 114, as shown in FIG. 1F by, for example, chemical vapor deposition (CVD), physical vapor deposition (PVD), atomic layer deposition (ALD), implantation, thermal diffusion, wet diffusion, etch-then-refill, electroless plating, electrochemical plating, sputtering, ion metal plasma, another deposition process, or any suitable combination thereof and without limitation. It will be appreciated that the enhancement layer 116 is deposited so as to cover all exposed facets of the fins 112, and the cross-sectional illustration of FIGS. 1A-1J is not intended to limit placement of the enhancement layer 116 solely to the sidewalls 113A-113B and top of the fins 112.

With respect to FIG. 1H, a second photoresist layer 118 is deposited and patterned on portions of the enhancement layer 116 corresponding to fins 112 for protection during subsequent processing. FIG. 1H illustrates the deposition of a photoresist layer and selective exposure via a photomask to visible light, ultraviolet light, deep ultraviolet light (i.e., DUV lithography), extreme ultraviolet light (i.e., EUV lithography), or so forth, followed by development of the exposed photoresist. The unexposed photoresist is then removed, resulting in the patterned second photoresist 118 shown in FIG. 1H.

Etching is then performed on the intermediate stage depicted in FIG. 1H to remove those fins 112 not protected by the second photoresist 118. In some embodiments, the portions uncovered by the second photoresist 118 are removed via etching, wherein the enhancement layer 116 functions as an etch stop layer. That is, the enhancement layer 116 comprises a suitable barrier material configured to protect the layers and components below from damage during subsequent etching processes. It will be appreciated that the enhancement layer 116 corresponds to a layer of material that has drastically different etching characteristics than the material to be etched, so as to stop or halt the etching processing of the layer deposited on the enhancement layer 116. According to one embodiment, the etching performed may include, for example and without limitation, plasma etching. That is, plasma etching corresponds to the removal of silicon (or other material) using plasma created by exciting ions in a gas, usually oxygen and carbon tetrafluoride (CF4). The excited ions collide with the material at the atomic level and remove the material. Other suitable plasma etching gases may include, for example and without limitation, octafluorocyclobutane (C4F8), argon (Ar), oxygen (O2), helium (He), fluoroform (CHF3), carbon tetrafluoride (CF4), difluoromethane (CH2F2), chlorine (Cl2), hydrogen bromide (HBr), or a combination thereof with a pressure ranging from about 1 m Torr to about 5 m Torr.

In some embodiments, this etching process to remove silicon may inadvertently impact the profile of outer fins, leading to lower quality and/or device breakdown. However, as shown in FIG. 1I, the inclusion of the enhancement layer 116 prevents shrinkage and allows each remaining fin 112 to have substantially uniform thickness. That is, the enhancement layer 116 prevents the plasma etching from removing material from the sidewalls 113A-113B of the fins 112 positioned adjacent the fins 112 that are removed, i.e., those fins positioned adjacent the newly formed trench region 120 resulting from removal of those fins unprotected by the second photoresist 118.

Accordingly, FIG. 1I illustrates the intermediate fabrication stage of a FinFET device after removal of the uncovered fins 112. In some embodiments, the process of removing the uncovered fins 112 may be referenced as defining the fin region of a FinFET device. As shown in FIG. 1I, the trench region 120 is depicted positioned adjacent to those fins 112 that were not removed. FIG. 1I further illustrates a FinFET region 122 on the substrate 102, as discussed in greater detail below. It will be appreciated that the second photoresist 118 and enhancement layer 116 remain illustrated in FIG. 1I, which are then removed resulting in the intermediate stage of fabrication of the FinFET device shown in FIG. 1J. In accordance with some embodiments, the second photoresist 118 and at least a portion of the enhancement layer 116, e.g., the portion along the sidewalls 113A-113B of the remaining fins 112, are removed via suitable removal processes. Such processes may include, for example and without limitation, plasma etching, wet etching, dry etching, or the like.

In accordance with some embodiments, FinFET device illustrated in FIGS. 1A-1J may be bulk FinFET, SOI FinFET, or the like. In some embodiments, the device device isolation structures may be LOCOS, STI, DTI, BOX, Deep_Well_Formation, or the like. In such embodiments, the enhancement layer 116 may have a thickness in the range of 1 A˜30 A. Such enhancement layer 116 may be construction of material comprising of Si, O, N, etc. Further, the enhancement layer material comprise of Si, Ge, O, C, N, P, As, B, Ga, at least 1% atomic concentration, formed by implantation, thermal diffusion, ALD diffusion, wet diffusion, etch-then-refill.

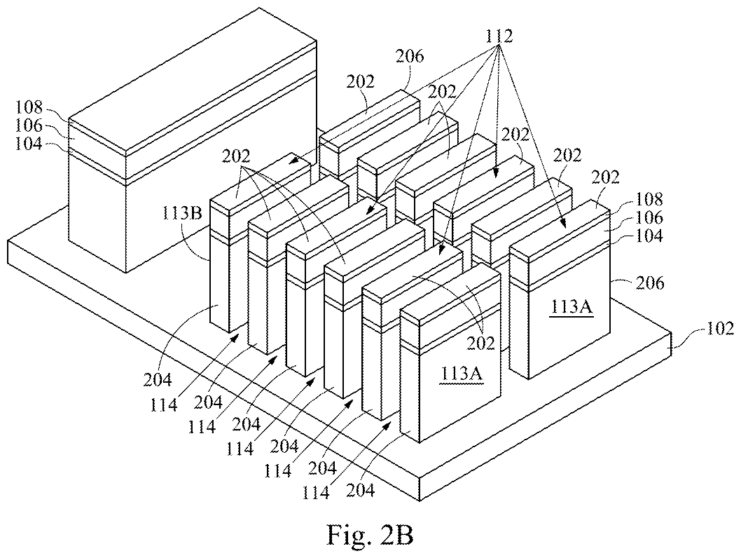

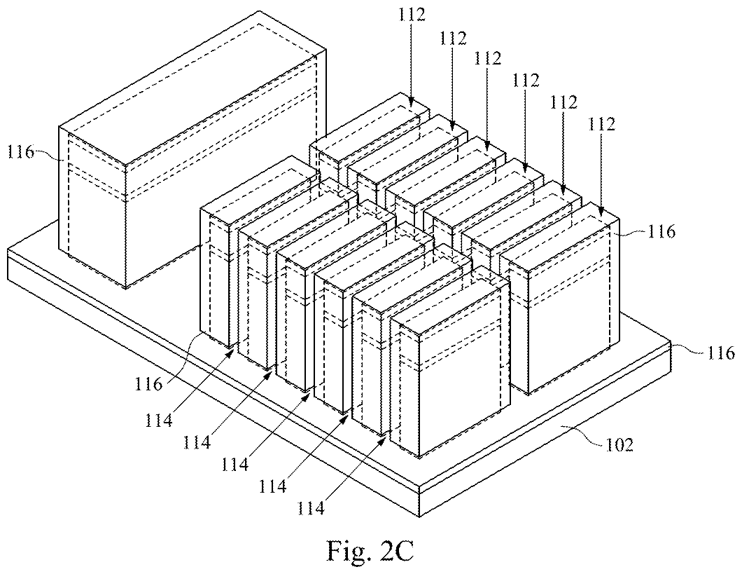

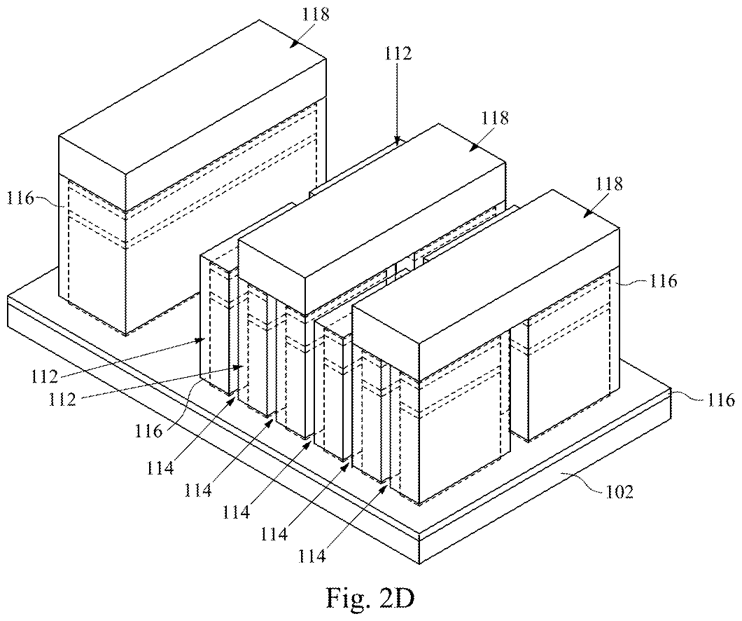

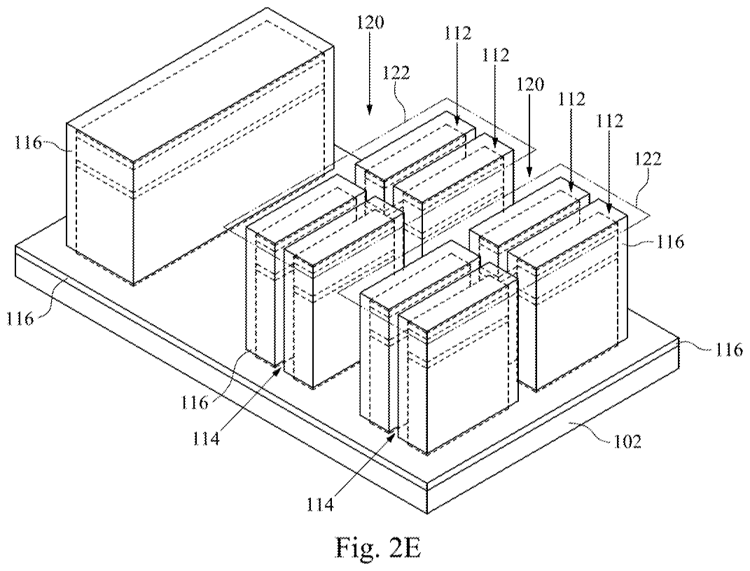

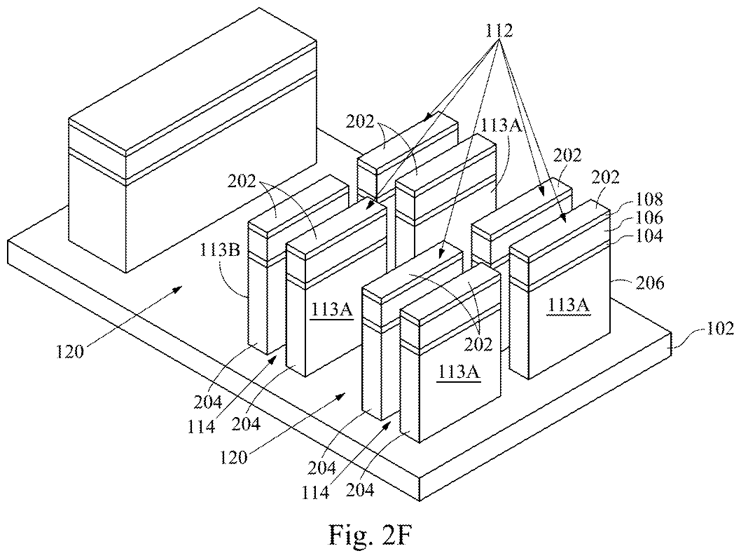

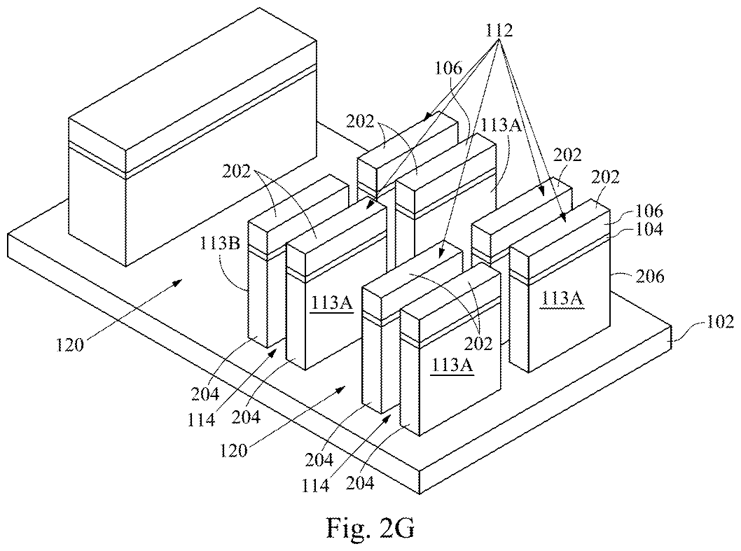

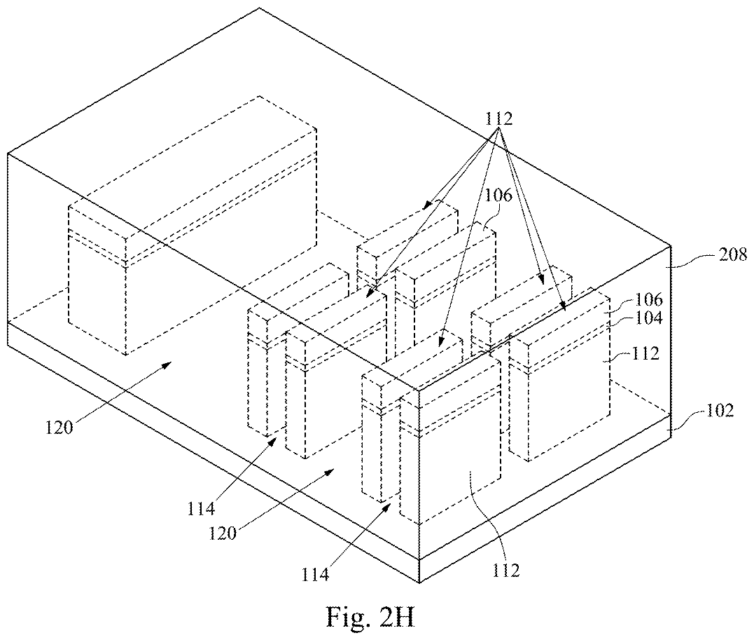

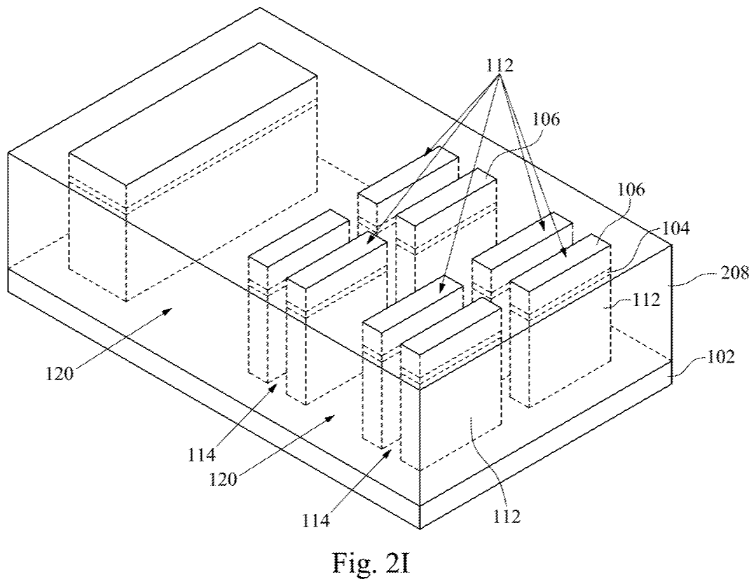

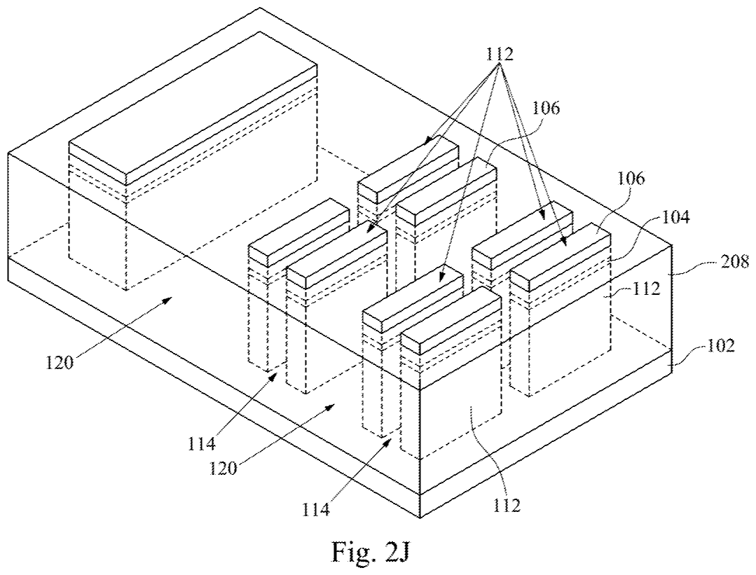

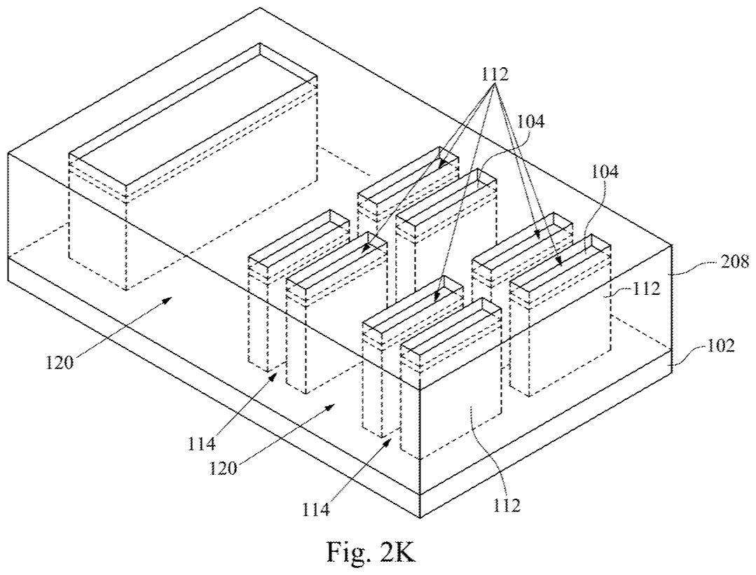

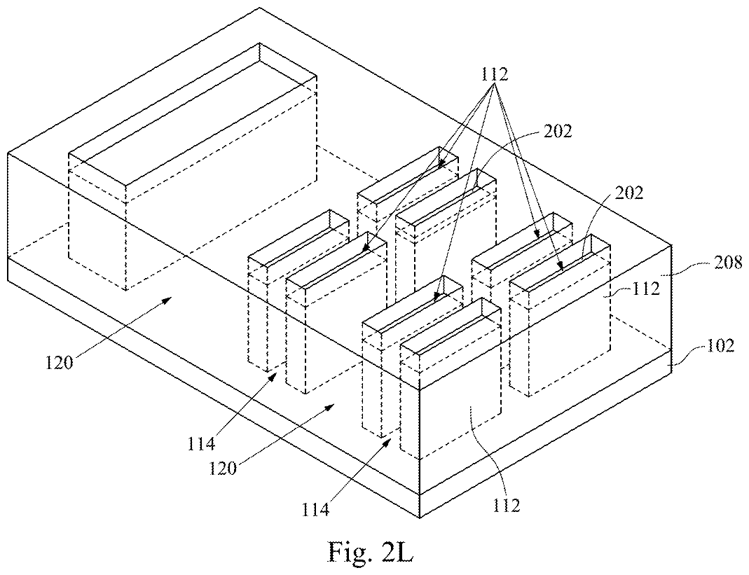

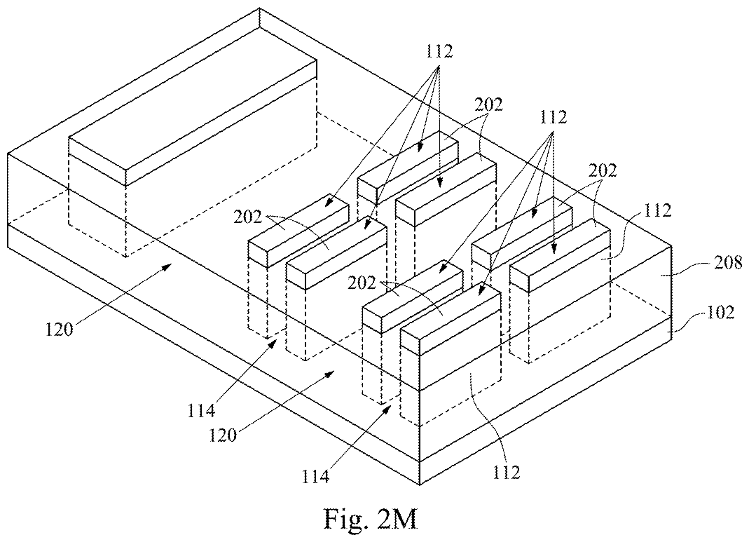

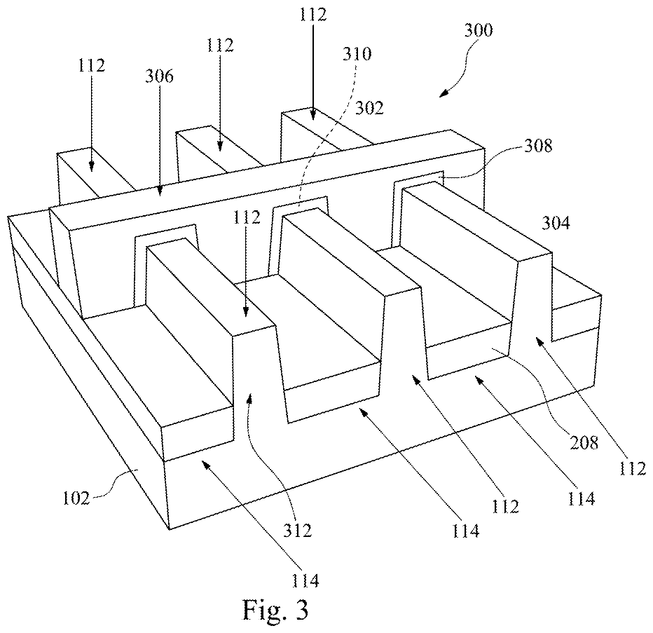

Turning now to FIGS. 2A-2M, there are shown three-dimensional illustrations of fabricating a FinFET device in accordance with some embodiments. It will be understood that the illustrations of FIGS. 2A-2M are not to scale, and are intended as examples to illustrate various steps of the method for fabrication of a FinFET device in accordance with embodiments disclosed herein. Accordingly, the heights of the fins, spacing therebetween, placement of source, drain, gate, etc. (as discussed further below) are merely intended to illustrate, without limiting, certain aspects of embodiments disclosed herein. The intermediate structure shown in FIG. 2A, includes a substrate 102, upon which are formed one or more layers of material, illustrated in FIG. 2A as a pad layer 104, a first insulative layer 106, and a hard mask layer 108. Further, a photoresist 110 is applied and patterned on the hard mask layer 108, as shown.

In accordance with one embodiment, an etching process is performed on the structure of FIG. 2A, whereupon portions uncovered by the photoresist 110 are removed. Suitable etching may include, for example and without limitation, a dry etching process, plasma etching process, a RIE process, a wet etching process, some other etching process, or a combination of the foregoing. Accordingly, FIG. 2B depicts initial formation of fins 112 of the structure after such etching and removal of the photoresist 110, along with device isolation structures 114 between each fin 112. As shown in FIG. 2B, each fin 112 includes a first sidewall 113A, a second sidewall 113B, a top 202, front 204, and a back 206. It will be appreciated that the fins 112 are illustrated as rectangular in shape for example purposes only, and non-perpendicular sides, faces, fronts, backs, etc., are contemplated herein.

FIG. 2C illustrates formation of the enhancement layer 116, which encapsulates each fin 112, formed on the sidewalls 113A-113B thereof, as well as the top 202, front 204 and back 206 of each fin 112. In accordance with some embodiments, the enhancement layer 116 may comprise silicon, oxygen, nitrogen, or the like. In further embodiments, the enhancement layer 116 may include Si, O, C, N, P, As, B, and/or Ga of at least 1% atomic concentration. The aforementioned enhancement layer 116 may be deposited in a thickness in the range of about 1 A to 30 A. As will be appreciated, the enhancement layer 116 may be deposited on the fins 112, sidewalls 113A-113B, tops 202, fronts 204, backs 206, substrate 102, and device isolation structures 114, as shown in FIG. 2C. Such formation of the enhancement layer 116 may be accomplished by, for example and without limitation, chemical vapor deposition (CVD), physical vapor deposition (PVD), atomic layer deposition (ALD), implantation, thermal diffusion, wet diffusion, etch-then-refill, electroless plating, electrochemical plating, sputtering, ion metal plasma, another deposition process, or any suitable combination thereof. As illustrated in FIG. 2C, and as previously referenced above with respect to FIG. 1G, all exposed facets of the fins 112 are suitably covered by the enhancement layer 116.

Turning now to FIG. 2D, there is shown the result of a deposition and patterning of a second photoresist layer 118 on portions of the enhancement layer 116 corresponding to fins 112 for protection during subsequent processing. FIG. 2D illustrates the deposition of a photoresist layer and selective exposure via a photomask to visible light, ultraviolet light, deep ultraviolet light (i.e., DUV lithography), extreme ultraviolet light (i.e., EUV lithography), or so forth, followed by development of the exposed photoresist. The unexposed photoresist is then removed, resulting in the patterned second photoresist 118 shown in FIG. 2D.

Etching is then performed on the intermediate stage depicted in FIG. 2D to remove those fins 112 not protected by the second photoresist 118. In some embodiments, the portions uncovered by the second photoresist 118 are removed via etching, wherein the enhancement layer 116 functions as an etch stop layer, i.e., a layer of material having drastically different etching characteristics than the material to be etched, so as to stop or halt the etching processing of the layer deposited on the enhancement layer 116. In some embodiments, the etching process to remove the extraneous fins (fins 112 uncovered by the photoresist 118), is a plasma etching process, removing silicon (and other material) of the fins 112 using plasma created by exciting ions in a gas, usually oxygen and CF4. The excited ions collide with the material at the atomic level and remove the material. As discussed above, this etching process to remove silicon may inadvertently impact the profile of outer fins, leading to lower quality and/or device breakdown. Accordingly, use of the enhancement layer 116 provides protection against such shrinkage of the fin profile. That is, the enhancement layer 116 reduces the etch rate in line end fins, such that plasma etching which may induce edge (ISO area) fin profile shrinkage in FinFET structures is avoided.

FIG. 2E provides an illustration of the advantage of utilizing the enhancement layer 116 in accordance with some embodiments. As shown in FIG. 2E, the inclusion of the enhancement layer 116 prevents shrinkage and allows each remaining fin 112 to have substantially uniform thickness. That is, the enhancement layer 116 prevents the plasma etching from removing material from the sidewalls 113A-113B of the fins 112 positioned adjacent the fins 112 that are removed, i.e., those fins positioned adjacent the newly formed trench region 120 resulting from removal of those fins unprotected by the second photoresist 118.

FIG. 2E illustrates the intermediate fabrication stage of a FinFET device after removal of the uncovered fins 112. In some embodiments, the process of removing the uncovered fins 112 may be referenced as defining the fin region of a FinFET device. As shown in FIG. 2E, the trench region 120 is depicted positioned adjacent to those fins 112 that were not removed. FIG. 2E further illustrates a FinFET region 122 on the substrate 102, as discussed in greater detail below. It will be appreciated that the enhancement layer 116 remains illustrated in FIG. 2E.

FIG. 2F illustrates an intermediate stage of fabrication of the FinFET device after removal of the enhancement layer 116 from the fins 112. As shown in FIG. 2F, at least a portion of the enhancement layer 116, e.g., the portion along the sidewalls 113A-113B, tops 202, fronts 204, and backs 206 of the remaining fins 112, are removed via suitable removal processes. Such processes may include, for example and without limitation, plasma etching, wet etching, dry etching, or the like. Next, the hard mask layer 108 is removed via suitable removal processes. In some embodiments, the hard mask layer 108 may be removed via chemical-mechanical polishing (CMP), a dry etching process, plasma etching process, a RIE process, a wet etching process, some other etching process, or a combination of the foregoing. FIG. 2G provides an illustrative example of the intermediate fabrication stage of the FinFET device subsequent to hard mask layer 108 removal.

An STI material 208 is then deposited on the structure, as depicted in FIG. 2H. As shown in FIG. 2H, the STI material 208 may comprise any suitable shall-trench-isolation (STI) material including, for example and without limitation, silicon oxide e.g., (SiO₂), silicon nitride (SiN), silicon oxynitride (SiON), fluoride-doped silicate glass (FSG), or a low-k dielectric material, and/or other suitable insulating material. In some embodiments, STI material 208 may comprise multiple layers of insulative materials. In some embodiments, the process of depositing the insulating material can include any deposition method suitable for flowable dielectric materials (e.g., flowable silicon oxide). For example, flowable silicon oxide or silicon nitride may be deposited as the STI material 208 using a flowable CVD (FCVD) process. The FCVD process can be followed by a wet anneal process. In some embodiments, the process of depositing the insulating material can include depositing a low-k dielectric material to form a liner. In some embodiments, a liner made of another suitable insulating material, can be placed between the STI material 208 in the device isolation structures 114 and adjacent fins 112.

A chemical mechanical polish (CMP) process is then performed to expose the first insulative layer 106 and reduce the STI material 208, as illustrated in FIG. 2I. In some embodiments, the hard mask layer 108 may remain prior to deposition of the STI material 208, and then be removed during this stage of processing. In FIG. 2J, the STI material 208 is etched to remove a portion thereof, further exposing the first insulative layer 106. This removal may be accomplished via electron beam (EB) operations, wet etching processes, dry etching processes, plasma etching processes, or the like.

FIG. 2K illustrates the subsequent removal of the first insulative layer 106, thereby exposing the pad layer 104. The removal of the first insulative layer 106 may be accomplished via etching operations including, for example and without limitation, dry etching, wet etching, plasma etching, or a suitable combination thereof. Thereafter, as shown in FIG. 2L, the pad layer 104 is removed from the top 202 of the fins 112, resulting in exposure of the fins 112 within the STI material 208. It will be appreciated that the removal of the pad layer 104 may be performed via etching, i.e., wet etching, dry etching, and/or plasma etching. FIG. 2M illustrates recessing of the fins 112 relative to the STI material 208 in accordance with some embodiments. As will be appreciated, fin recess may correspond to defining of the fin height of a fin 112 of the FinFET device. FIG. 2M depicts one example recessing of the fins 112, whereupon a portion of the STI material 208 is removed. As indicated above, removal of such STI material 208 may be accomplished via wet etching, dry etching, plasma etching, or the like.

Turning now to FIG. 3, there is shown a three-dimensional representative example of a FinFET device 300 fabricated in accordance with the illustrated processes described above with respect to FIGS. 1A-2M. As shown in FIG. 3, the FinFET device 300 includes the substrate 102, device isolation structures 114 with STI material 208, one or more fins 112, a source region 302, a drain region 304, a gate structure 306, a gate oxide component 308, and a channel 310. As shown in FIG. 3, the FinFET device 300 is formed on the substrate 102. The device isolation structures 114 with STI material are formed to isolate the FinFET device 300 from neighboring FinFETs and/or from neighboring active and passive elements. As shown in FIG. 3, each fin 112 extends perpendicularly outward from the top surface of the substrate 102. In accordance with the fabrication methods and processes described above, i.e., use of the enhancement layer 116 during fin formation, it will be appreciated that the outer fins 112 of the FinFET device 300 are uniform in thickness 312.

During operation of FinFET device 300, current flows from the source region 302 to the drain region 304, through channel 310, in response to a voltage applied to the gate 306. Source and drain regions 302 and 306 may be doped with either a positive or a negative species to provide charge reservoirs for the FinFET device 300. The gate structure 306 surrounds three sides of each fin 112 to control the current flow through channel 110. In some embodiments, the gate 306 is a multi-layered structure that includes (not shown) a gate electrode, a gate dielectric (e.g., the gate oxide component 308) that separates the gate 306 from fins 112, and sidewall spacers, as will be appreciated.

When the voltage applied to the gate electrode exceeds a certain threshold voltage, the FinFET device 300 switches on and current flows through channel 310. If the applied voltage drops below the threshold voltage, the FinFET device 300 shuts off, and current ceases to flow through channel 310. In accordance with some embodiments, the wrap-around gate structure 306 influences the channel 310 from three sides, thereby improving control of the conduction properties of the channel 310 relative to planar FETs. Such improved control reduces leakage of charge from channel 310 to the substrate 102, or from the source and drain regions 302 and 304 to the substrate 102. Furthermore, because the current-carrying capacity of the channel 310 is much greater than that of a planar conducting channel, switching characteristics of a FinFET are also improved over those of planar FETs. In using the methods described above, i.e., application of the enhancement layer 116, uniformity across fins 112, particularly the outer fins 112 is achieved, reducing breakdown of the FinFET 300.

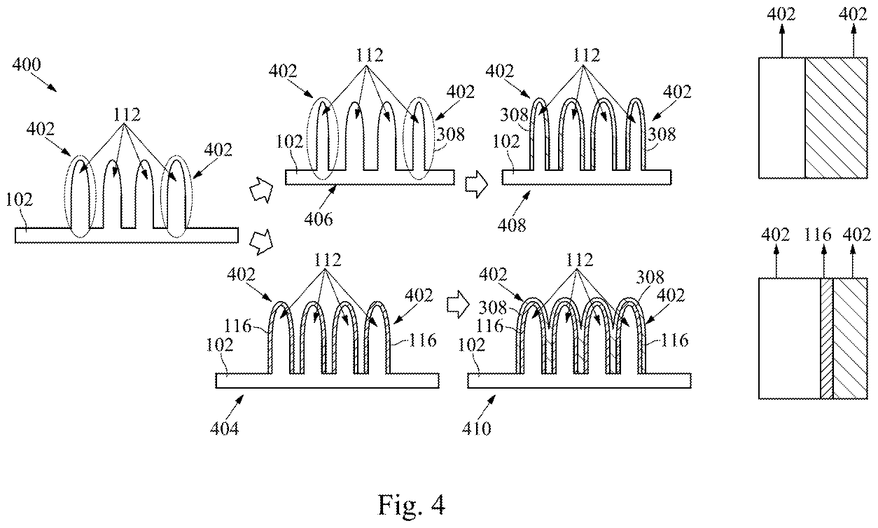

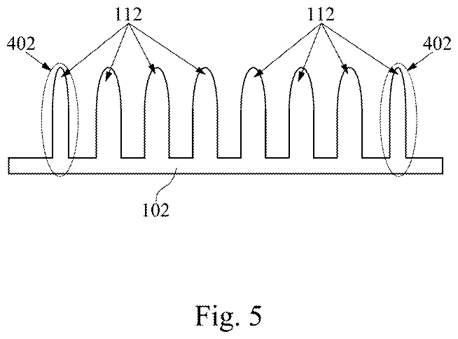

Referring now to FIG. 4, there is shown a comparative illustration of the use of the enhancement layer 116 during fin formation. As shown at 400, initial definition of the fins 112 is performed. The edge fins 402 are circled to indicate those fins 112 most impacted by the use of an enhancement layer 116. At 404, an enhancement layer 116 is applied to the fins 112. Thereafter, fin cutting is performed, i.e., plasma etching is performed to remove unneeded fins (as referenced above in FIGS. 1A-2M). As a result of the aforementioned etching, it is illustrated at 406 that the edge fins 402 are noticeably thinner than the interior fins 112. When no enhancement layer 116 is applied, the outer fins 402 shown at 406 are noticeably thinner than the interior fins 112. This is a result of the etching process, which removes portions of the fins 112. FIG. 5 also provides an illustration of a greater number of fins 112, whereupon the outer fins 402 are noticeably thinner than the interior. As a non-limiting example, if the thickness of the fins 112 is designed to be 7 nm, the exterior fins 402 may be 4.2-5.2 nm in thickness, potentially causing breakdown. Returning to FIG. 4, a gate liner or oxide 308 is then applied to the fins 112, as illustrated at 408 (no enhancement layer 116) and 410 (fins having enhancement layer 116). In contrast, as indicated at 408, the application of the enhancement layer 116, as discussed above, maintains the thickness of each fin 112, including the exterior fins 402.

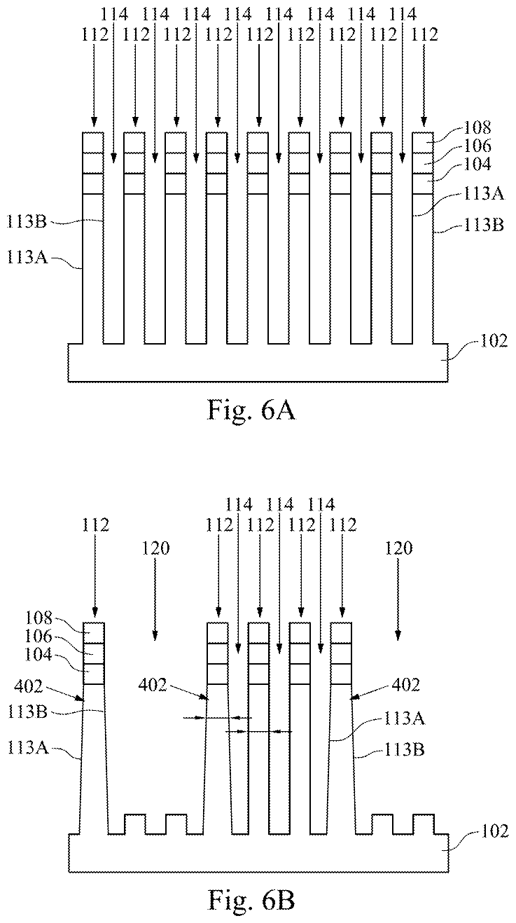

FIGS. 6A and 6B provide a further comparative illustration of narrowing, i.e., thinning of the outer fins 402 in the absence of the enhancement layer 116. It will be appreciated that FIG. 6A corresponds to FIG. 1F, as described above. FIG. 6B illustrates the impact of not including the enhancement layer 116, as the outer fins 402 are thinner as a result of silicon loss during etching, in contrast to FIG. 1J, discussed above.

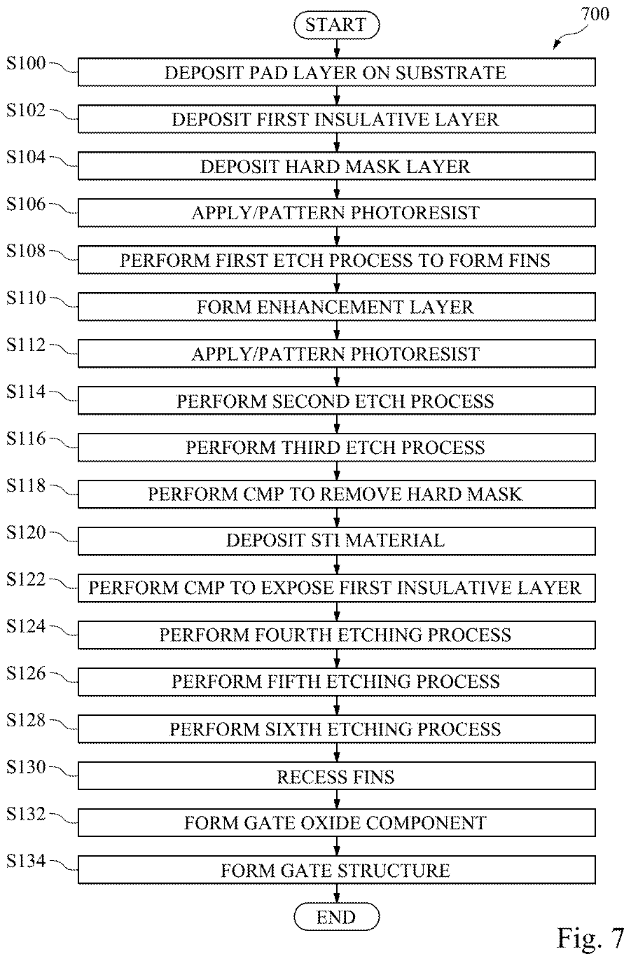

Turning now to FIG. 7, there is shown a method 700 for fabricating a FinFET structure/device in accordance with some embodiments. The method begins at S100, whereupon a pad layer 104 is deposited on a substrate 102. The substrate 102 may include a semiconductor material, such as an elemental semiconductor including Si and Ge; a compound or alloy semiconductor including SiC, SiGe, GaAs, GaP, GaAsP, AlInAs, AlGaAs, GaInAs, InAs, GaInP, InP, InSb, and/or GaInAsP; or a combination thereof. In some embodiments, the pad layer 104 may comprise, for example and without limitation may be implemented as a suitable dielectric, i.e., insulative, material including, for example and without limitation, silicon dioxide (SiO₂) material, silicon nitride (SiNₓ) material, or the like. Suitable mechanisms for depositing the pad layer 104 may include, for example and without limitation, chemical vapor deposition (CVD), physical vapor deposition (PVD), atomic layer deposition (ALD), electroless plating, electrochemical plating, sputtering, ion metal plasma, another deposition process, or any suitable combination thereof.

At step S102, a first insulative layer 106 is formed on the pad layer 104. In accordance with some embodiments, the first insulative layer 106 may comprise any suitable dielectric material including, for example and without limitation, silicon dioxide (SiO₂) material, silicon nitride (SiNₓ) material, or the like. Suitable mechanisms for depositing the first insulative layer 106 may include, for example and without limitation, chemical vapor deposition (CVD), physical vapor deposition (PVD), atomic layer deposition (ALD), electroless plating, electrochemical plating, sputtering, ion metal plasma, another deposition process, or any suitable combination thereof. In one example embodiment, the pad layer 104 and the first insulative layer 106 comprise different materials. In a further embodiment, the first insulative layer 106 may be deposited as a silicon nitride layer.

A hard mask layer 108 is then formed on the first insulative layer 106, at step S104. In accordance with some embodiments, the hard mask layer 108 may comprise, for example and without limitation a nitride or an oxide material. As will be appreciated, deposition, such as, for example and without limitation, chemical vapor deposition (CVD), physical vapor deposition (PVD), atomic layer deposition (ALD), electroless plating, electrochemical plating, sputtering, ion metal plasma, another deposition process, or any suitable combination thereof, may be used for applying the hard mask layer 108 onto the first insulative layer 106.

At step S106, a photoresist 110 is applied and patterned on the hard mask layer 108. At step S108, a first etch process is performed, whereupon portions uncovered by the photoresist 110 are removed so as to form a plurality of fins 112. Suitable etching may include, for example and without limitation, a dry etching process, plasma etching process, a RIE process, a wet etching process, some other etching process, or a combination of the foregoing. As a result of the first etching process, a plurality of fins 112 are initially formed following removal of the photoresist 110.

At step S110, an enhancement layer 116 is formed on the fins 112 and substrate 102. In accordance with one embodiment, the enhancement layer encapsulates each fin 112, the sidewalls 113A-113B, device isolation structures 114, and the top 202, front 204 and back 206 of each fin 112. In accordance with some embodiments, the enhancement layer 116 may comprise silicon, oxygen, nitrogen, or the like. In further embodiments, the enhancement layer 116 may include Si, O, C, N, P, As, B, and/or Ga of at least 1% atomic concentration. The aforementioned enhancement layer 116 may be deposited in a thickness in the range of about 1 A to 30 A. Such formation of the enhancement layer 116 may be accomplished by, for example and without limitation, chemical vapor deposition (CVD), physical vapor deposition (PVD), atomic layer deposition (ALD), implantation, thermal diffusion, wet diffusion, etch-then-refill, electroless plating, electrochemical plating, sputtering, ion metal plasma, another deposition process, or any suitable combination thereof.

At step S112, a second photoresist layer 118 is applied and patterned on portions of the enhancement layer 116 corresponding to fins 112 for protection during subsequent processing. A second etch process is then performed at step S114 to remove those fins 112 not protected by the second photoresist 118. In some embodiments, the portions uncovered by the second photoresist 118 are removed via etching, wherein the enhancement layer 116 functions as an etch stop layer, i.e., a layer of material having drastically different etching characteristics than the material to be etched, so as to stop or halt the etching processing of the layer deposited on the enhancement layer 116. In some embodiments, the etching process to remove the extraneous fins (fins 112 uncovered by the photoresist 118), is a plasma etching process, removing silicon (and other material) of the fins 112 using plasma created by exciting ions in a gas, usually oxygen and CF4. The excited ions collide with the material at the atomic level and remove the material. As discussed above, this etching process to remove silicon may inadvertently impact the profile of outer fins, leading to lower quality and/or device breakdown. Accordingly, use of the enhancement layer 116 provides protection against such shrinkage of the fin profile.

At step S116, a third etching process is performed to remove at least a portion of the enhancement layer 116. That is, at least a portion of the enhancement layer 116, e.g., the portion along the sidewalls 113A-113B, tops 202, fronts 204, and backs 206 of the remaining fins 112, are removed via suitable removal processes. Such processes may include, for example and without limitation, plasma etching, wet etching, dry etching, or the like. Thereafter, at step S118, chemical mechanical polishing is performed to remove the hard mask layer 108. At step S120, an STI material 208 is then deposited. In accordance with some embodiments, the STI material 208 may comprise any suitable shall-trench-isolation (STI) material including, for example and without limitation, silicon oxide e.g., (SiO₂), silicon nitride (SiN), silicon oxynitride (SiON), fluoride-doped silicate glass (FSG), or a low-k dielectric material, and/or other suitable insulating material. In some embodiments, STI material 208 may comprise multiple layers of insulative materials. In some embodiments, the process of depositing the insulating material can include any deposition method suitable for flowable dielectric materials (e.g., flowable silicon oxide). For example, flowable silicon oxide or silicon nitride may be deposited as the STI material 208 using a flowable CVD (FCVD) process. The FCVD process can be followed by a wet anneal process. In some embodiments, the process of depositing the insulating material can include depositing a low-k dielectric material to form a liner. In some embodiments, a liner made of another suitable insulating material, can be placed between the STI material 208 in the device isolation structures 114 and adjacent fins 112.

At step S122, chemical mechanical polish (CMP) processing is then performed to expose the first insulative layer 106 and reduce the STI material 208. At step S124, a fourth etching process is performed to remove a portion of the STI material 208, further exposing the first insulative layer 106. This removal may be accomplished via electron beam (EB) operations, wet etching processes, dry etching processes, plasma etching processes, or the like.

The first insulative layer 106 is then removed via fifth etching process at step S126, thereby exposing the pad layer 104. The removal of the first insulative layer 106 may be accomplished via etching operations including, for example and without limitation, dry etching, wet etching, plasma etching, or a suitable combination thereof. At step S128 sixth etching process is performed to remove the pad layer 104 from the top 202 of the fins 112, resulting in exposure of the fins 112 within the STI material 208. It will be appreciated that the removal of the pad layer 104 may be performed via etching, i.e., wet etching, dry etching, and/or plasma etching. At step S130, recessing of the fins 112 is performed relative to the STI material 208. As will be appreciated, fin recess may correspond to defining of the fin height of a fin 112 of the FinFET device. As indicated above, removal of such STI material 208 may be accomplished via wet etching, dry etching, plasma etching, or the like. At step S132, a gate oxide component 308 is formed on the fins 112 of the FinFET device. Thereafter, at step S134, a gate structure 306 is formed on the FinFET device.

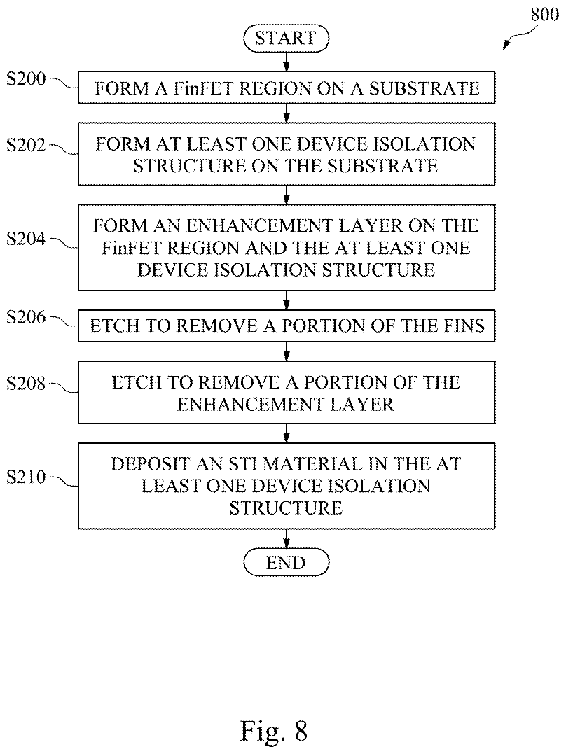

Referring now to FIG. 8, there is shown a method 800 of forming a semiconductor device incorporating one or more FinFET structures/devices fabricated in accordance with the example methodology set forth above with respect to FIG. 7. A FinFET region 122 is first formed on a substrate 102 at step S200. The FinFET region 122, as illustrated in FIGS. 1A-1J, includes one or more fins 112. At step S202, at least one device isolation structure 114 is formed on the substrate 102 between each of the fins 112. At step S204, an enhancement layer 116 is formed on the fins 112 and in the device isolation structures 114. At step S206, a portion of the fins 112 are removed, forming a trench region 120. At step S208, etching is performed to remove a portion of the enhancement layer 116. Thereafter, at step S210, an STI material 208 is deposited in the device isolation structures 114.

In accordance with a first embodiment, there is provided a method for forming a semiconductor device. The method includes performing a first etching process to define one or more fins and corresponding device isolation structures on a substrate. The method further includes forming an enhancement layer on each of the fins, such that the enhancement layer encapsulates each fin. The method further performs a second etching process to remove one or more of the fins, and performs a third etching process to remove a portion of the enhancement layer. The method also includes depositing an STI material on the fins and the device isolation structures, followed by recessing the fins relative to the STI material.

In accordance with a second embodiment, there is provided a semiconductor device that includes a substrate. The substrate includes a FinFET region formed on the substrate, with the FinFET region including one or more fins. The semiconductor device further includes one or more device isolation structures formed on the substrate and positioned next to the one or more fins. In addition, the semiconductor device includes an enhancement layer that is formed on a portion of the one or more fins.

In accordance with a third embodiment, there is provided a method of forming a semiconductor device. The method includes forming a FinFET region on a substrate, with the FinFET region including one or more fins. The method further includes forming one or more device isolation structures on the substrate adjacent to the one or more fins. The method also includes forming an enhancement layer on the one or more fins and the one or more device isolation structures. In addition, the method includes etching to remove at least one of the fins.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
performing a first etching process to define a plurality of fins and a corresponding plurality of device isolation structures on a substrate;
forming an enhancement layer on each of the plurality of fins, the enhancement layer encapsulating each of the plurality of fins;
performing a second etching process to remove at least one fin of the plurality of fins;
performing a third etching process to remove at least a portion of the enhancement layer;
depositing an STI material on the plurality of fins and the corresponding plurality of device isolation structures; and
recessing the plurality of fins relative to the STI material.

2. The method of claim 1, wherein the enhancement layer comprises at least one of an oxide or a nitride.

3. The method of claim 2, wherein the enhancement layer is a silicon nitride.

4. The method of claim 3, wherein the enhancement layer is deposited in the range of about 1 angstrom to 35 angstroms.

5. The method of claim 2, further comprising forming a gate oxide component on at least one of the plurality of fins.

6. The method of claim 5, further comprising forming a gate structure on the gate oxide component.

7. The method of claim 2, prior to performing the first etching process, further comprising:
depositing a pad layer on the substrate;
depositing a first insulative layer on the pad layer;
depositing a hard mask layer on the first insulative layer; and
patterning a photoresist on the hard mask layer, wherein the first etching process is performed in accordance with the patterned photoresist.

8. The method of claim 7, further comprising performing a chemical mechanical polish process to remove the hard mask layer prior to depositing the STI material.

9. The method of claim 8, further comprising performing a chemical mechanical polish process to expose the first insulative layer.

10. The method of claim 9, further comprising performing a fourth etching process to remove a portion of the STI material.

11. The method of claim 10, further comprising performing a fifth etching process to remove the first insulative layer.

12. The method of claim 11, further comprising performing a sixth etching process to remove the pad layer.

13. A semiconductor device, comprising:
a substrate comprising a FinFET region formed on the substrate, the FinFET region comprising at least one fin;
at least one device isolation structure formed on the substrate, the at least one device isolation structure positioned adjacent the at least one fin; and
an enhancement layer formed on at least a portion of the at least one fin.

14. The semiconductor device of claim 13, wherein the device isolation structures comprises at least one of a local oxidation of silicon (LOCOS) region, a shallow trench isolation (STI), a deep trench isolation (DTI), a buffer oxide (BOX) region, or a deep-well-formation.

15. The semiconductor device of claim 13, wherein the enhancement layer comprises at least one of silicon, oxygen, or nitrogen.

16. The semiconductor device of claim 15, wherein enhancement layer further comprises at least one of Si, O, C, N, P, As, B, or Ga of at least 1% atomic concentration.

17. The semiconductor device of claim 13, wherein the enhancement layer is deposited in a thickness in the range of about 1 A to 30 A.

18. A method of forming a semiconductor device, comprising:
forming a FinFET region on a substrate, the FinFET region comprising a plurality of fins;
forming at least one device isolation structure on the substrate adjacent to at least one fin of the plurality thereof;
forming an enhancement layer on the at least one fin and the at least one device isolation structure; and
etching to remove at least one of the plurality of fins.

19. The method of claim 18, further comprising depositing an STI material on the least one device isolation structure.

20. The method of claim 18, wherein the enhancement layer comprises at least one of Si, O, C, N, P, As, B, or Ga of at least 1% atomic concentration; and wherein the enhancement layer is deposited in a thickness in the range of about 1 A to 30 A.
